(19) United States
(12) Patent Application Publication
(10) Pub. No.: US 2015/0162299 A1
(43) Pub. Date: Jun. 11, 2015

(54) INTEGRATED WIRE BONDER AND 3D MEASUREMENT SYSTEM WITH DEFECT REJECTION

(71) Applicant: Fairchild Semiconductor Corporation, San Jose, CA (US)

(72) Inventor: Daren W. Keller, Madbury, NH (US)

(21) Appl. No.: 14/523,338

(22) Filed: Oct. 24, 2014

Related U.S. Application Data
(60) Provisional application No. 61/914,573, filed on Dec. 11, 2013.

(51) Int. Cl. H01L 23/00; H01L 21/66; H01L 21/67

(52) U.S. Cl. CPC H01L 24/78; H01L 24/85; H01L 21/67253; H01L 21/67282; H01L 21/67288; H01L 22/12; H01L 22/26; H01L 2224/789; H01L 2224/48177; H01L 2224/859; H01L 2924/14

(57) ABSTRACT

An apparatus comprises a wire bonder system including a wire bonding device, a measuring device and a rejection device. The wire bonding device is configured to attach wire bond type electrical interconnect to an electronic assembly. A wire bond is formed between a first semiconductor device and a second electronic device to form at least a portion of the electronic assembly. The measuring device is configured to perform a three dimensional measurement associated with a wire bond, and the rejection device is configured to identify an electronic assembly for rejection according to the three dimensional wire bond measurement.

### CLAIM OF PRIORITY

This application claims the benefit of U.S. Provisional Patent Application Ser. No. 61/914,573, filed on Dec. 11, 2013, the benefit of priority of which is claimed hereby, and which is incorporated by reference herein in its entirety.

### BACKGROUND

Wire bonding refers to the process of adding electrical interconnection between a semiconductor device (e.g., an integrated circuit or IC) and its packaging or to another electronic device, such as a lead frame for the semiconductor device or a printed circuit board (PCB) for example. Once the wire bonding process is complete, the wire bonds are manually inspected to identify defects, such as by an operator using a microscope. The present inventor has recognized a need for improvements in the wire bonding process.

### OVERVIEW

This document relates generally to systems, devices, and methods for assembly of electronic devices and systems, and in particular to wire bonding of semiconductor devices. As explained previously herein, wire bonds can be manually inspected to identify defects once the wire bonding process is complete. Because the inspection is separate from the bonding process, one or more lots may be completed before a problem is discovered by the manual inspection. This may result in a large quantity of defective product. Additionally, manual inspection adds cost and time to the manufacturing process. The present subject matter can improve the manufacturing process by integrating inspection in real time with the wire bonding process rather than performing inspection as an off-line step.

An apparatus example of the present subject matter includes a wire bonder system having a wire bonding device, a measuring device and a rejection device. The wire bonding device is configured to attach wire bond type electrical interconnect to an electronic assembly. A wire bond is formed between a first semiconductor device and a second electronic device to form at least a portion of the electronic assembly. The measuring device is configured to perform a three dimensional measurement associated with a wire bond, and the rejection device is configured to identify an electronic assembly for rejection according to the three dimensional wire bond measurement.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a flow diagram of an example of a method of wire bonding an electronic device or electronic assembly.

FIG. 2 is an illustration of an example of a wire bonder system.

FIG. 3 is an illustration of another example of a wire bonder system.

FIG. 4 shows a diagram of process flow in a wire bonding system having feedback control.

### DETAILED DESCRIPTION

As explained previously herein, the wire bonding process can be improved if inspection is integrated with building the product. The inspection is then done in real time as assembly occurs rather than offline after wire bonding has been completed.

FIG. 1 is a flow diagram of an example of a method 100 of wire bonding an electronic device or electronic assembly. At block 105, one or more wire bonds are attached between a first semiconductor device and a second electronic device using a wire bonder system. The one or more wire bonds form one or more electrical interconnections between the first semiconductor device and the second electronic device. The first semiconductor device, the second electronic device, and the electrical interconnections form at least a portion of an electronic assembly. The first semiconductor device can include an IC or other semiconductor device. The second electronic device can include packaging for the first semiconductor device such as a lead frame for example. The second electronic device can include a printed circuit board (PCB) or substrate. In certain examples, the second electronic device is a second semiconductor device.

At block 110, one or more three dimensional measurements associated with the one or more wire bonds is performed by a measuring device of the wire bonder system. Some examples of three dimensional measurements associated with the one or more wire bonds include, among other things, the loop height of the one or more wire bonds and a position of the one or more wire bonds. The measurements are performed automatically by the measuring device and the measurements do not need to involve an operator. The measuring device may receive the electronic assembly from a wire bonding station of the wire bonder system. The wire bonding station may pass the electronic assembly to the measuring device as the wire bonding is completed for that assembly. The measuring can be done in real time while the wire bonder system is on line and performing the wire bonding. The three dimensional measurements can be used to detect defects in a wire bond of the assembly such as, among other things, a lifted wire bond, a shorted wire bond, and a wire bond that is too long or too high (excessive loop height).

At block 115, an electronic assembly is selectively identified for rejection by a rejection device of the wire bonder system according to the three dimensional wire bond measurement. The rejection device may identify an electronic assembly for rejection when the three dimensional measurement does not satisfy a specified range for the three dimensional measurement. For example, an electronic assembly may be identified for rejection when a three dimensional measure of wire loop height is higher than a specified loop height threshold, or higher or lower than a specified range of values of loop height.

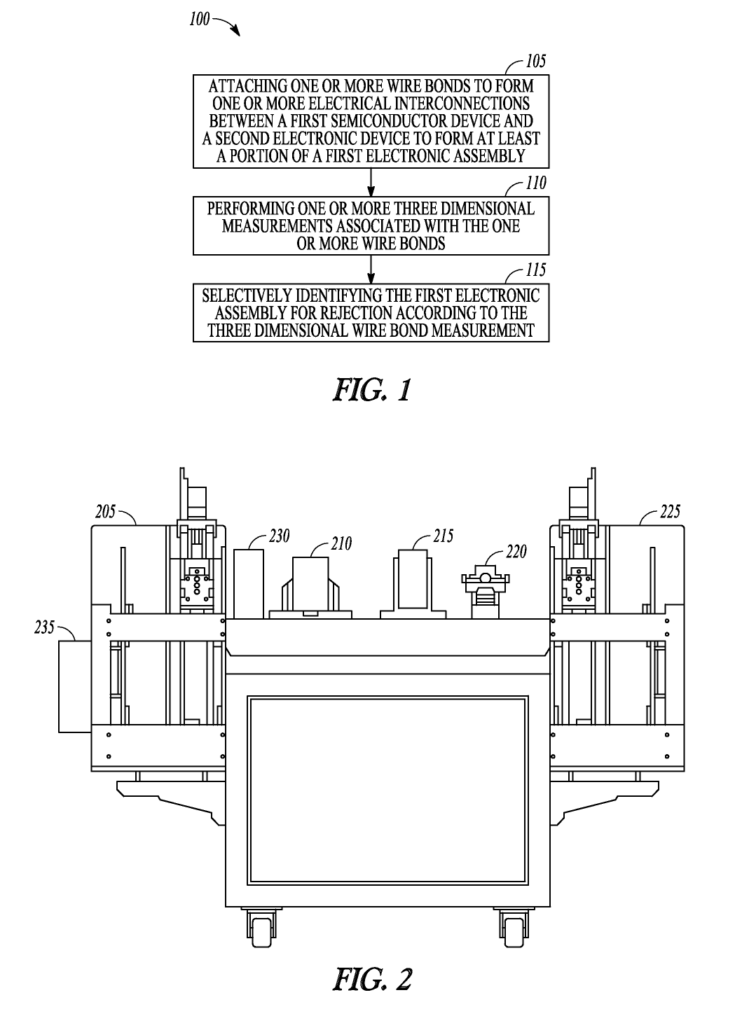

FIG. 2 is an illustration of an example of a wire bonder system. The system includes a wire bonding device 210, a measuring device 215, and a rejection device 220. Electronic devices for wire bonding may be fed into the wire bonding device 210 using an input handler 205 or input magazine handler as part of a manufacturing process. The wire bonding device 210 attaches wire bond type electrical interconnect to the received devices, such as wire or ribbons having a diameter of micrometers for example. Wire bonds are formed between a first semiconductor device and a second electronic device to form at least a portion of an electronic assembly. Wire bonds formed by the wire bonding device 210 may include wire or ribbon that comprises one or more of, among other things, copper, aluminum, or gold, and the wire bonds may be attached to one or more contact pads of the first semiconductor device. The semiconductor device can include a discrete part (e.g., a diode, or transistor) or may include an IC with many semiconductor circuits, such as a processor or application specific integrated circuit (ASIC) for example. The second electronic device may include at least part of a package for the semiconductor device or may include a PCB or substrate on which the first semiconductor device is attached. In certain examples, the second electronic device may be a second semiconductor device. The ends of the wire bonds may be attached or bonded to contact pads using one or both of solder and epoxy. The wire bonding device may apply wire bonds to additional semiconductor devices or electronic devices that are included in the electronic assembly. Completed assemblies are collected by the output handler 225 or output magazine handler.

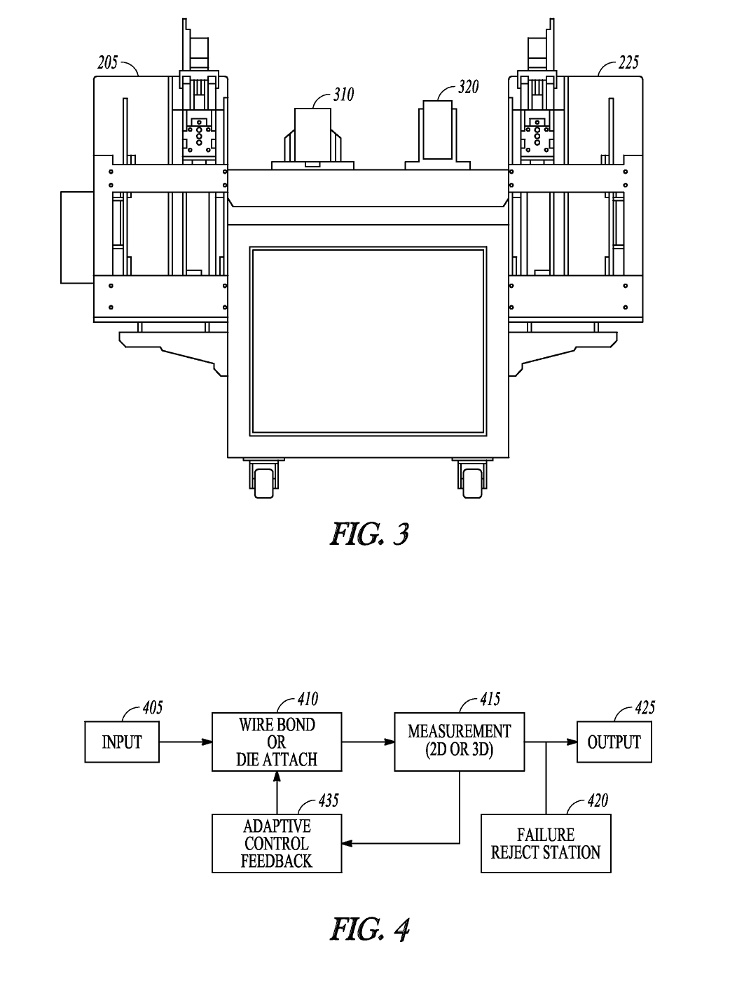

The measuring device 215 may be separate from the wire bonding device 210 and may receive electronic assemblies from the wire bonding device 210. FIG. 3 is an illustration of another example of a wire bonder system. In the example shown, the wire bonding device and measuring device are integrated into a single wire bonding/inspection module 310. The wire bonding can be inspected as the wire bonding is performed or when the wire bonding is completed, but before the electronic assembly is passed to the rejection device 320.

Returning to FIG. 2, the measuring device 215 performs a three dimensional measurement associated with a wire bond. Some examples of three dimensional measurements associated with the one or more wire bonds include, among other things, the loop height of the one or more wire bonds, length of the one or more wire bonds, the position of the one or more wire bonds, and the amount of rotation of one or both of the first semiconductor device and the second electronic device.

The measuring device 215 may include a three dimensional imaging device (e.g., a 3D camera) that obtains images of the electronic assembly. The images may include one or more predetermined regions of interest of the electronic assembly completed by the wire bonding device 210. The measuring device 215 may include a processor, such as a microprocessor or digital signal processor to process images obtained by the three dimensional imaging device. Pattern recognition can be used to identify and measure wire bonds. For instance, the processor may use an edge detection algorithm on pixels of images obtained using the imaging device to identify the wire or ribbon of the wire bond from a background of the image. Features of the wire bond may be identified and coordinates of the detected wire bond can be used to calculate parameters such as wire bond loop height and location. Features of the devices to be bonded can be identified to determine device rotation and tilt. An approach to three dimensional measurements in electronic assembly can be found in Chung et al., Paris Cooperation Treaty (PCT) Application Publication No. WO2010090605, filed Feb. 8, 2010, which is incorporated herein by reference in its entirety.

In some examples, the measuring device 215 includes an infrared imaging device to obtain a thermal image of the electronic assembly. The measuring device 215 may include a processor to process the thermal image to measure parameters of wire bonds. In some examples, the measuring device 215 includes a laser measuring or imaging device. The measuring device 215 may determine features of the wire bonds using interferometry.

The three dimensional measurements may be made in real time as the wire bonding device completes the bonding of assemblies and the assemblies move to the measuring device, or the measurements may be made while the bonding is being performed if the two devices are integrated. Three dimensional measurements can provide greater detail and accuracy than a two dimensional measurement. However, processing a three-dimensional image to characterize wire bonds may take longer than two dimensional measurements. In certain examples, the measuring device 215 can be switched to performing two dimensional analysis if faster processing is desired. For instance, the imaging device may include a stereo camera to create three dimensional images. The measuring device 215 can be switched to using just one camera to create a two dimensional image for processing. Another method to speed up processing is to sample the assemblies for measurement. The measuring device may perform the three dimensional measurement on less than all of the plurality of electronic assemblies formed by the wire bonding device (e.g., 1 in 5 or 1 in 10).

In some examples, the wire bonder system includes a die attach device 230. The die attach device 230 may be integrated into the wire bonding device 210. The die attach device 230 may mount a semiconductor device or other electronic device onto a substrate or PCB as part of the assembly process. In some examples, the die attach device 230 mounts the first semiconductor device next to one or more other electronic devices. In some examples, the die attach device 230 stacks the first semiconductor device and at least a second semiconductor device as part of the electronic assembly. The measuring device 215 may generate a three dimensional measurement of a stack height of the first semiconductor device and the second semiconductor device.

The rejection device 220 identifies an electronic assembly for rejection according to the three dimensional wire bond measurement. In certain examples, the rejection device 220 identifies an electronic assembly for rejection when a three dimensional measurement associated with the wire bond does not satisfy a specified range for the three dimensional measurement. For instance the measurement may be higher or lower than a range of acceptable values, or may be higher or lower than a specified threshold value for the measurement.

According to some examples, the rejection device 220 selectively alters an electronic assembly according to the three dimensional wire bond measurement. The alteration may be a mechanical alteration that makes it easy to identify defective parts downstream in the manufacturing process. In some examples, the rejection device 220 forms an electrical discontinuity in a wire bond when a three dimensional measurement associated with the wire bond does not satisfy a specified range for the three dimensional measurement. In this way, defective parts may be identified later in the manufacturing process using electrical testing (e.g., an electrical test to assess one or both of functionality and electrical continuity).

In some variations, the rejection device 220 includes a wire cutting mechanism to cut a wire bond when a defect is identified. The wire may be cut through heating or slicing using a blade or laser. In certain variations, the rejection device 220 includes a lifting mechanism to lift a wire in the wire bond away from a bond pad when a defect is identified. In certain variations, the rejection device 220 includes a drill mechanism to mill out at least a portion of the lead frame when a defect is identified. In certain variations, the rejection device 220 includes a die punch mechanism to punch out at least a portion of the wire bond when a defect is identified. This may be useful if the error is in a die attach parameter and the measurement is not associated with a wire bond. The wire bond that is altered may be the defective wire bond or may be any wire bond convenient for cutting, lifting, drilling, or punching to cause the assembly to fail the electrical continuity test. Defective devices may be culled by the rejection device or may be culled from the process by a device downstream in the assembly process.

In some examples, the rejection device 220 marks a defective electronic assembly. In variations, the rejection device 220 marks a defective electronic assembly with a color or scribe. In certain variations the mark is machine recognizable and a device downstream from the wire bonder system culls the defective part from the manufacturing process. In certain variations, the mark is large enough to be recognized by an operator without a visual aid such as a microscope and the parts are culled by the operator.

In some examples, the wire bonder system includes a controller 235. The controller 235 can be implemented using hardware circuits, firmware, software or any combination of hardware, firmware and software. Examples, include a processor such as a microprocessor, application specific integrated circuit (ASIC), or other type of processor. The controller 235 is configured (by the hardware, firmware, or software) to perform the functions described. These functions correspond to modules, which are software, hardware, firmware or any combination thereof. Multiple functions may be performed in one or more of the modules.

The wire bonder system can include a memory circuit integral to the controller or electrically coupled to the controller 235. The rejection device 220 may store an identifier in the memory circuit to identify a defective electronic assembly determined using one or more three dimensional measurements. The defective assembly may then be tracked or mapped electronically. The electronic mapping may enable a downstream device to cull the defective part from the process using the identifier. In some examples, the wire bonder system may generate an error message when a three dimensional measurement associated with the wire bond does not satisfy a specified range for the three dimensional measurement. An operator may then take steps to correct the error.

Integrating the inspection with the wire bonding can provide real time feedback control of the wire bonding process. The measuring device 215 may communicate at least one three dimensional measurement between the measuring device and the wire bonding device of the wire bonder system. In some examples, the three dimensional measurement is received by the controller 235. The controller 235 adjusts at least one wire bonding parameter of the wire bonding device in response to the communicated measurement. In some examples, the controller 235 adjusts a wire bonding parameter when a three dimensional measurement associated with the wire bond does not satisfy a specified range for the three dimensional measurement. For instance, if the measurement indicates that the wire bond position is outside a specified range, the controller 235 may adjust the position to bring the measurement back into range. In some examples, the controller 235 calculates an error between the measurement and the specified value for the position and adjusts the wire bond position to minimize the error. Similarly, the controller 235 may provide feedback adjustment of other wire bond measurements, such as wire bond loop height and wire bond length for example.

In some examples, the controller 235 receives a three dimensional measure of rotation of a device, such as one or more devices placed on a substrate during a die attach step of the manufacturing process. If the three dimensional measurement indicates that the wire bond position is outside a specified range, the controller 235 may adjust the rotation to bring the measurement back into range. This may aid in the initial setup of the wire bonder system. An operator may physically setup up an initial wire bond position. This initial position may be incorrect and may be incorrect intentionally. The wire bonder system may use feedback control to zero in on the correct setting by minimizing a programmed error to the correct position. The controller may take different actions based on the three dimensional measurements. The action taken may depend on one or more of the failure type, the number of failures, and the severity of the failure. In certain examples, the action is based on statistical process control (SPC) analysis. For instance, the controller 235 may not try to adjust a wire bonder or die attach parameter until the error in the measurement exceeds a threshold or is outside the specified range. The controller 235 may merely log the measurements or indicate a drift in the measurement until the error reaches the predetermined severity.

In some examples, the wire bonder system includes a user interface in electrical communication with the controller 235. The user interface may include one or more of a keypad, keyboard, computer mouse, and a display. The controller may be programmed to display one or more of the three dimensional measurements. In some variations, the controller 235 generates an alert when a three dimensional measurement is outside of a specified range, or the measurement otherwise indicates that the wire bonding process is in error. The alert may be displayed using the user interface. In certain variations, the alert is communicated (e.g., a signal communicated using wired or wireless communication) to a separate device or system for display to a user. In certain variations, one or more of the three dimensional measurements is communicated and stored in a data base (e.g., a data base stored on a server) for future SPC data analysis or real time data analysis. If the SPC analysis detects abnormal conditions or conditions outside of specifications, the alert may be used (e.g., by the controller, a separate device, or a user) to stop the wire bonding and/or die attach process or stop the process at the end of the current lot of assemblies.

FIG. 4 shows a diagram of process flow in a wire bonding system having feedback control. At block 405, electronic devices such as semiconductor devices are input into the wire bonding system. At block 410, the devices are subject to die attach or wire bonding to form an electronic assembly or subassembly. At block 415, one or more measurements (e.g., a three dimensional measurement or a two dimensional measurement) are determined. The measurements are associated with one or both of wire bonding and die attach. The one or more measurements are fed back at block 435 to maintain the process parameters within a specified range. One or both of the die attach process and the wire bonding process may be adjusted if the measurements indicate error.

At block 420 defective devices are identified, such as by any of the methods described previously herein for example. Devices without defects are passed to the output of the wire bonding station at block 425. Devices with defects may be collected at the reject station or may be passed to the output for later culling by another device.

The systems, devices, and methods described herein provide several advantages over an inspection (manual or automated) that is done offline and separate from the assembly process. Inspection and monitoring of one or both of wire bonding and die attach is done in real time as the wire bonding and die attach are performed. This reduces time and floor space needed for separate inspection after the process is off line. It also may eliminate the need of an operator for inspection, which reduces time and cost. Inspection and monitoring in real time with the wire bonding and die attach allows process characterization and SPC of the system. It also enables immediate machine-based interaction to resolve a detected error. This permits defective devices to be quickly removed from the assembly process to reduce downstream assembly costs resulting from using defective parts.

ADDITIONAL NOTES AND EXAMPLES

Example 1 can include subject matter (such as an apparatus) comprising a wire bonder system, the wire bonder system including a wire bonding device configured to attach wire bond type electrical interconnect to an electronic assembly. A wire bond is formed between a first semiconductor device and a second electronic device to form at least a portion of the electronic assembly. The subject matter can also include a measuring device configured to perform a three dimensional measurement associated with a wire bond, and a rejection device configured to identify an electronic assembly for rejection according to the three dimensional wire bond measurement.

In Example 2, the subject matter of Example 1 can optionally include a controller configured to receive at least one three dimensional measurement from the measuring device and adjust at least one wire bonding parameter of the wire bonding device in response to the communicated measurement.

In Example 3, the subject matter of Example 2 can optionally include a measuring device configured to generate a measure of rotation of the semiconductor device, wherein the controller is optionally configured to adjust at least one wire bonding parameter in response to the generated measure of rotation.

In Example 4, the subject matter of one or any combination of Examples 1-3 can optionally include a rejection device configured to selectively alter an electronic assembly according to the three dimensional wire bond measurement.

In Example 5, the subject matter of one or any combination of Examples 1-4 can optionally include a rejection device configured to form an electrical discontinuity in a wire bond when a three dimensional measurement associated with the wire bond does not satisfy a specified range for the three dimensional measurement.

In Example 6, the subject matter of one or any combination of Examples 1-5 can optionally include a rejection device configured to mark the at least a portion of an electronic assembly when a three dimensional measurement associated with the wire bond does not satisfy a specified range for the three dimensional measurement.

In Example 7, the subject matter of one or any combination of Examples 1-6 can optionally include a memory circuit electrically coupled to or integral to the rejection device, wherein the rejection device is configured to store an identifier in the memory circuit for the at least a portion an electronic assembly when a three dimensional measurement associated with the wire bond does not satisfy a specified range for the three dimensional measurement.

In Example 8, the subject matter of one or any combination of Examples 1-7 can optionally include a measuring device configured to generate a three dimensional measurement of one or both of a loop height of a wire bond and a position of a wire bond.

In Example 9, the subject matter of one or any combination of Examples 1-8 can optionally include a die attach device configured to stack the first semiconductor device and at least a second semiconductor device as part of the electronic assembly, and wherein the measuring device is configured to generate a three dimensional measurement of a stack height of the first semiconductor device and the at least a second semiconductor device.

In Examples 10, the subject matter of one or any combination of Examples 1-9 can optionally include a measuring device including a three dimensional imaging device.

In Example 11, the subject matter of one or any combination of Examples 1-10 can optionally include a measuring device including at least one of a laser or an infrared imaging device.

In Example 12, the subject matter of one or any combination of Examples 1-11 can optionally include a wire bonding device configured to form the at least one portion of an electronic assembly for a plurality of electronic assemblies, and wherein the measuring device is configured to perform the three dimensional measurement on less than all of the plurality of electronic assemblies formed by the wire bonding device.

In Example 13, the subject matter of one or any combination of Examples 1-12 can optionally include a wire bonding device configured to form a wire bond between the first semiconductor device and at least one of a lead frame for the first semiconductor device or a second semiconductor device.

Example 14 can include subject matter (such as a method, a means for performing acts, or a machine-readable medium including instructions that, when performed by the machine, cause the machine to perform acts), or can optionally be combined with the subject matter of one or any combination of Examples 1-13 to include such subject matter, comprising attaching, by a wire bonder system, one or more wire bonds to form one or more electrical interconnections between a first semiconductor device and a second electronic device to form at least a portion of a first electronic assembly, performing, by a measuring device of the wire bonder system, one or more three dimensional measurements associated with the one or more wire bonds, and selectively identifying, by a rejection device of the wire bonder system, the first electronic assembly for rejection according to the three dimensional wire bond measurement.

In Example 15, the subject matter of Example 14 can optionally include forming, by the wire bonder system, at least a portion of a second electronic assembly during the performing of the one or more three dimensional measurements associated with the one or more wire bonds of the first electronic assembly.

In Example 16, the subject matter of one or both of Examples 14 and 15 can optionally include initiating one or more three dimensional measurements associated with one or more wire bonds of a second electronic assembly during the altering of the first electronic assembly.

In Example 17, the subject matter of one or any combination of Examples 14-16 can optionally include communicating at least one three dimensional measurement between the measuring device and a wire bonding device of the wire bonder system, and adjusting, by the wire bonder system, at least one wire bonding parameter in response to the communicated measurement.

In Example 18, the subject matter of or any combination of Examples 14-17 can optionally include generating a three dimensional measurement of one or more of loop height of a wire bond and position of a wire bond.

In Example 19, the subject matter of one or any combination of Examples 14-18 can optionally include stacking the first semiconductor device and at least a second semiconductor device to form the at least a portion of the first electronic assembly, wherein performing one or more three dimensional measurements includes generating a three dimensional measurement of an IC stack height of the first semiconductor device and the at least a second semiconductor device. In Example 20, the subject matter of one or any combination of Examples 14-19 can optionally include performing one or more three dimensional measurements using a three dimensional imaging device.

In Example 21, the subject matter of one or any combination of Examples 14-20 can optionally include removing electrical continuity of a wire bond when a three dimensional measurement associated with the wire bond does not satisfy a specified range for the three dimensional measurement.

In Example 22, the subject matter of one or any combination of Examples 14-21 can optionally include selectively marking at least one of the IC dice or the electronic device of the first electronic assembly when a three dimensional measurement associated with the wire bond does not satisfy a specified range for the three dimensional measurement.

Example 23 can include, or can optionally be combined with any portion or combination of any portions of any one or more of Examples 1-22 to include, subject matter that can include means for performing any one or more of the functions of Examples 1-22, or a machine-readable medium including instructions that, when performed by a machine, cause the machine to perform any one or more of the functions of Examples 1-22.

These non-limiting examples can be combined in any permutation or combination.

The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code can form portions of computer program products. Further, the code can be tangibly stored on one or more volatile or non-volatile computer-readable media during execution or at other times. These computer-readable media can include, but are not limited to, hard disks, removable magnetic disks, removable optical disks (e.g., compact disks and digital video disks), magnetic cassettes, memory cards or sticks, random access memories (RAM's), read only memories (ROM's), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. §1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. An apparatus comprising a wire bonder system, the wire bonder system including:
a wire bonding device configured to attach wire bond type electrical interconnect to an electronic assembly, wherein a wire bond is formed between a first semiconductor device and a second electronic device to form at least a portion of the electronic assembly;
a measuring device configured to perform a three dimensional measurement associated with a wire bond; and
a rejection device configured to identify an electronic assembly for rejection according to the three dimensional wire bond measurement.

2. The apparatus of claim 1, including a controller, wherein the controller is configured to receive at least one three dimensional measurement from the measuring device and adjust at least one wire bonding parameter of the wire bonding device in response to the communicated measurement.

3. The apparatus of claim 2, wherein the measuring device is configured to generate a measure of rotation of the semiconductor device, wherein the controller is configured to adjust at least one wire bonding parameter in response to the generated measure of rotation.

4. The apparatus of claim 1, wherein the rejection device is configured to selectively alter an electronic assembly according to the three dimensional wire bond measurement.

5. The apparatus of claim 1, wherein the rejection device is configured to form an electrical discontinuity in a wire bond when a three dimensional measurement associated with the wire bond does not satisfy a specified range for the three dimensional measurement.

6. The apparatus of claim 1, wherein the rejection device is configured to mark the at least a portion of an electronic assembly when a three dimensional measurement associated with the wire bond does not satisfy a specified range for the three dimensional measurement.

7. The apparatus of claim 1, wherein wire bonder system includes a memory circuit electrically coupled to or integral to the rejection device, wherein the rejection device is configured to store an identifier in the memory circuit for the at least a portion an electronic assembly when a three dimensional measurement associated with the wire bond does not satisfy a specified range for the three dimensional measurement.

8. The apparatus of claim 1, wherein the measuring device is configured to generate a three dimensional measurement of one or both of a loop height of a wire bond and a position of a wire bond.

9. The apparatus of claim 1, including a die attach device configured to stack the first semiconductor device and at least a second semiconductor device as part of the electronic assembly, and wherein the measuring device is configured to generate a three dimensional measurement of a stack height of the first semiconductor device and the at least a second semiconductor device.

10. The apparatus of claim 1, wherein the measuring device includes a three dimensional imaging device.

11. The apparatus of claim 1, wherein the measuring device includes at least one of a laser or an infrared imaging device.

12. The apparatus of claim 1, wherein the wire bonding device is configured to form the at least one portion of an electronic assembly for a plurality of electronic assemblies, and wherein the measuring device is configured to perform the three dimensional measurement on less than all of the plurality of electronic assemblies formed by the wire bonding device.

13. The apparatus of claim 1, wherein the wire bonding device is configured to form a wire bond between the first semiconductor device and at least one of a lead frame for the first semiconductor device or a second semiconductor device.

14. A method comprising:
attaching, by a wire bonder system, one or more wire bonds to form one or more electrical interconnections between a first semiconductor device and a second electronic device to form at least a portion of a first electronic assembly;
performing, by a measuring device of the wire bonder system, one or more three dimensional measurements associated with the one or more wire bonds; and
selectively identifying, by a rejection device of the wire bonder system, the first electronic assembly for rejection according to the three dimensional wire bond measurement.

15. The method of claim 14, including forming, by the wire bonder system, at least a portion of a second electronic assembly during the performing of the one or more three dimensional measurements associated with the one or more wire bonds of the first electronic assembly.

16. The method of claim 14, including initiating one or more three dimensional measurements associated with one or more wire bonds of a second electronic assembly during the altering of the first electronic assembly.

17. The method of claim 14, including
communicating at least one three dimensional measurement between the measuring device and a wire bonding device of the wire bonder system; and
adjusting, by the wire bonder system, at least one wire bonding parameter in response to the communicated measurement.

18. The method of claim 14, wherein performing one or more three dimensional measurements includes generating a three dimensional measurement of one or more of loop height of a wire bond and position of a wire bond.

19. The method of claim 14, further including stacking the first semiconductor device and at least a second semiconductor device to form the at least a portion of the first electronic assembly, wherein performing one or more three dimensional measurements includes generating a three dimensional measurement of an IC stack height of the first semiconductor device and the at least a second semiconductor device.

20. The method of claim 14, wherein performing one or more three dimensional measurements includes performing one or more three dimensional measurements using a three dimensional imaging device.

21. The method of claim 14, wherein selectively altering the first electronic assembly includes removing electrical continuity of a wire bond when a three dimensional measurement associated with the wire bond does not satisfy a specified range for the three dimensional measurement.

22. The method of claim 14, wherein selectively altering the first electronic assembly includes marking at least one of the IC dice or the electronic device of the first electronic assembly when a three dimensional measurement associated with the wire bond does not satisfy a specified range for the three dimensional measurement.
